(19) United States
(12) Patent Application Publication
(10) Pub. No.: US 2026/0150746 A1
(43) Pub. Date: May 28, 2026

(54) PACKAGE STRUCTURE AND METHOD OF MANUFACTURING THE SAME

(71) Applicant: PowerX Semiconductor Corporation, Hsinchu County (TW)

(72) Inventors: Jing-Yao CHANG, Hsinchu County (TW); Chen-Min CHEN, Hsinchu County (TW); Tung-Han CHUANG, Hsinchu County (TW)

(21) Appl. No.: 19/347,740

(22) Filed: Oct. 2, 2025

(30) Foreign Application Priority Data
Oct. 9, 2024 (TW) 113138571

(51) Int. Cl. H01L 23/00

(52) U.S. Cl. CPC H10W 72/50; H10W 72/075; H10W 72/30; H10W 72/851; H10W 72/07511; H10W 72/07533; H10W 72/5434; H10W 72/884; H10W 90/734; H10W 90/754

(57) ABSTRACT

A package structure includes a substrate, a substrate pad on the substrate, a chip over the substrate, a chip pad and a dielectric layer on the chip, a metal pressure-resistant layer, an adhesion layer, and an interconnection conductor. The metal pressure-resistant layer is disposed on and electrically connected to the chip pad, and has a nano-twinned structure. The chip pad is between the chip and the metal pressure-resistant layer, and the dielectric layer is separated from the metal pressure-resistant layer. The adhesion layer is between the metal pressure-resistant layer and the chip pad, and formed from a material different from a material of the metal pressure-resistant layer. The interconnection conductor is electrically connected to the metal pressure-resistant layer and the substrate pad. A width of the chip pad is greater than a width of the first adhesion layer and a width of the metal pressure-resistant layer.

### CROSS-REFERENCE TO RELATED APPLICATION

This application claims priority to Taiwan Application Serial Number 113138571, filed Oct. 9, 2024, which is herein incorporated by reference in its entirety.

### BACKGROUND

### Technical field

The present invention relate to packaging technology, and more particularly, to a package structure having a metal pressure-resistant layer and a method of manufacturing the same.

### Description of Related Art

The inverter in the electric vehicle motor control unit is the most critical component for converting electrical energy into kinetic energy, in which the most important part affecting the efficiency of electrical energy conversion is the power electronic module. The voltage/current specifications of power module components for automotive motors reach 600V/450A, which is much higher than those of general power modules and consumer electronic integrated circuits (ICs), and must pass various reliability tests of the automotive standard AEC-Q101. Therefore, the threshold for its packaging technology and materials is extremely high.

Power module packaging includes bonding a surface-metallized substrate to a metal heat-dissipating baseplate, then fixing a power semiconductor chip onto the substrate (referred to as die bonding), followed by interconnection between a pad on the power IC chip and a pad on the substrate. Conventional interconnection technology uses an aluminum wire or aluminum ribbon thicker than 200 micrometers (μm) for ultrasonic wire bonding, so that the aluminum wire or aluminum ribbon is bonded to the pad on the power IC chip. However, the aluminum wire or aluminum ribbon has a relatively low melting point (for example, below 700° C.), which can no longer meet the requirements of power modules with higher currents and high voltages.

In recent years, the packaging industry has begun to experiment with copper wires or copper ribbons, or silver wires or silver ribbons. These materials not only have better electrical and thermal conductivity than aluminum wires or aluminum ribbons, but also have better material strength and reliability than aluminum wires or aluminum ribbons. However, copper wires, copper ribbons, silver wires, and silver ribbons have much higher hardness than aluminum wires or aluminum ribbons. During the ultrasonic wire bonding process, they often cause cracking of power IC chips, which is a problem urgently needing solution in current power module packaging.

### SUMMARY

One aspect of the present disclosure relates to a package structure, including a substrate, a first substrate pad, a chip, a chip pad, a dielectric layer, a metal pressure-resistant layer, a first adhesion layer, and an interconnection conductor. The first substrate pad is disposed on the substrate. The chip is disposed over the substrate and having a first side surface and a second side surface opposite to the first side surface. The second side surface faces the substrate. The chip pad is located on the first side surface of the chip. The dielectric layer is disposed in the same layer as the chip pad. The metal pressure-resistant layer is disposed on the chip pad, electrically connected to the chip pad, and having a first nano-twinned structure. The chip pad is disposed between the first side surface of the chip and the metal pressure-resistant layer, and the dielectric layer is separated from the metal pressure-resistant layer. The first adhesion layer is sandwiched between the metal pressure-resistant layer and the chip pad, and formed from a material different from a material of the metal pressure-resistant layer. The interconnection conductor has one end electrically connected to the metal pressure-resistant layer and the other end electrically connected to the first substrate pad. A width of the chip pad is greater than a width of the first adhesion layer and a width of the metal pressure-resistant layer.

A further aspect of the present disclosure relates to a method of manufacturing a package structure including providing a chip that has a first side surface and a second side surface opposite to the first side surface; disposing a chip pad that is located on the first side surface of the chip; disposing a dielectric layer that is disposed in the same layer as the chip pad; forming a first adhesion layer on the chip pad; forming a metal pressure-resistant layer having a first nano-twinned structure over the chip pad, such that the metal pressure-resistant layer is electrically connected to the chip pad, wherein the chip pad is disposed between the first side surface of the chip and the metal pressure-resistant layer, the dielectric layer is separated from the metal pressure-resistant layer, and the first adhesion layer is sandwiched between the metal pressure-resistant layer and the chip pad and formed from a material different from a material of the metal pressure-resistant layer; providing a substrate having a substrate pad, in which the second side surface of the chip faces the substrate; bonding the chip to the substrate; and electrically connecting the metal pressure-resistant layer to the substrate pad via an interconnection conductor, in which a width of the chip pad is greater than a width of the first adhesion layer and a width of the metal pressure-resistant layer.

A further aspect of the present disclosure relates to a package structure, including a substrate, a first substrate pad, a chip, a chip pad, a metal pressure-resistant layer, a first adhesion layer, and an interconnection conductor. The first substrate pad is disposed on the substrate. The chip is disposed over the substrate. The chip pad is located on a first side surface of the chip. The metal pressure-resistant layer is electrically connected to the chip pad and has a nano-twinned structure. The first adhesion layer is sandwiched between the metal pressure-resistant layer and the chip pad, and formed from a material different from a material of the metal pressure-resistant layer. The interconnection conductor has one end electrically connected to the metal pressure-resistant layer and the other end electrically connected to the first substrate pad. A width of the chip pad is greater than a width of the first adhesion layer and a width of the metal pressure-resistant layer. The nano-twinned structure is concentrated in a staircase arrangement or floating arrangement in an upper region of the metal pressure-resistant layer and a remaining region of the metal pressure-resistant layer consists of randomly arranged grains.

### BRIEF DESCRIPTION OF THE DRAWINGS

Various aspects of the present disclosure will be described in detail below with reference to the drawings. It should be noted that according to standard practices in the industry, various components are not drawn to scale and are used for illustrative purposes only. In fact, the dimensions of the elements may be arbitrarily enlarged or reduced to clearly show the components in embodiments of the present invention. It should also be noted that the drawings only illustrate typical embodiments of the present disclosure and should therefore not be considered as limiting its scope. The present disclosure is equally applicable to other embodiments.

FIGS. 1 to 4 are partial cross-sectional views illustrating different process stages of forming a package structure according to some embodiments of the present disclosure.

FIG. 5 shows a cross-sectional metallographic image of a SiC/Cr/Cu structure obtained using a focused ion beam according to some embodiments.

FIG. 6 shows a cross-sectional metallographic image of a SiC/Cr/Ni/Ag structure obtained using a focused ion beam according to some embodiments.

FIG. 7 shows a cross-sectional metallographic image of a SiC/Cr/nt-Cu structure obtained using a focused ion beam according to some embodiments.

FIG. 8 shows a cross-sectional metallographic image of a SiC/Cr/nt-Ag structure obtained using a focused ion beam according to some embodiments.

### DETAILED DESCRIPTION

The disclosure below provides many embodiments or examples for implementing different components of the provided subject matter. Specific examples of each component and its arrangement are described below to simplify the description of the embodiments of the present invention. Of course, these are merely examples and are not intended to limit the embodiments of the present invention. For example, if the description mentions that a first component is formed over a second component, it may include embodiments where the first and second components are in direct contact, or may also include embodiments where additional components are formed between the first and second components so that they are not in direct contact. In addition, in the embodiments of the present invention, reference numbers and/or letters may be repeated in various examples. Such repetition is for the sake of brevity and clarity and is not intended to indicate relationships between the different embodiments and/or configurations discussed.

Some variations of the embodiments are described below. In the embodiments of different drawings and descriptions, similar reference numerals are used to designate similar components. It is to be understood that additional steps can be provided before, during, and after the method, and some of the described steps may be replaced or deleted in other embodiments of the method.

Furthermore, spatially relative terms such as “below,” “beneath,” “lower,” “above,” “upper,” and the like may be used herein for ease of describing the relationship between an element(s) or component(s) and another element(s) or component(s) in the drawings. Spatially relative terms are intended to encompass different orientations of the device in use or operation, and orientations depicted in the drawings. When the device is oriented differently (rotated 90 degrees or at other orientations), spatially relative descriptors used herein will be interpreted relative to the reconfigured orientation.

The terminology used herein is merely for the purpose of describing particular embodiments and is not intended to limit the concepts of the present invention. Unless the context clearly indicates otherwise, singular expressions used herein include plural expressions. In the Description, it is to be understood that terms such as “comprising,” “having,” and “including” are intended to indicate the existence of features, numbers, steps, actions, components, parts, or combinations thereof disclosed in the Description, and are not intended to preclude the possibility that one or more other features, numbers, steps, actions, components, parts, or combinations thereof may exist or may be added.

Some embodiments of the present invention are described below. Additional steps can be provided before, during, and/or after the plurality of stages described in these embodiments. Some of the described stages may be replaced or omitted in different embodiments. The package structure may include additional components. Some of the described components may be replaced or omitted in different embodiments. Although some discussed embodiments are implemented with steps in a specific order, these steps may be performed in another logical order.

When ultrasonic wire bonding is performed using copper wires, copper ribbons, silver wires, or silver ribbons, a problem of cracking in power IC chips is frequently caused. For this problem, one solution is to bond a copper plate/foil onto a surface of a pad on a power IC chip by means of silver sintering to block an external load from ultrasonic wire bonding. However, silver sintering needs to be performed at a temperature above 250° C. Therefore, extremely high thermal stress is generated during a silver sintering process, causing damage to the power IC chip. Moreover, sintered silver paste contains a large number of voids, thereby reducing the electrical conductivity and thermal conductivity of the overall power module. Additionally, the process cost is also relatively high.

A further solution is to plate a copper conductive layer with a thickness approaching 10 micrometers on a surface of a pad on a power IC chip to block an external load from ultrasonic wire bonding. However, grains of the conventional copper conductive layer are arranged randomly, and the material thereof is relatively soft, thereby providing a limited stress-blocking effect. Therefore, when ultrasonic wire bonding is performed using copper wires, copper ribbons, silver wires, or silver ribbons, a larger load needs to be applied, and the power IC chip may still easily crack. Especially silicon carbide (SiC) compound semiconductor chips are extremely brittle and further prone to cracking than general silicon chips.

The present disclosure provides a package structure having a metal pressure-resistant layer. The metal pressure-resistant layer disposed over a chip, due to its nano-twinned structure, can effectively enhance an atomic diffusion reaction of a metal wire or ribbon during ultrasonic wire bonding and accelerate formation of a bonding interface. Therefore, its load can be reduced to avoid chip cracking when the ultrasonic wire bonding is performed. In addition, the nano-twinned structure has high hardness, which can further protect the underlying chip from cracking when ultrasonic wire bonding is performed using copper wires, copper ribbons, silver wires, or silver ribbons. Particularly, an interface between the conventional randomly grained copper conductive layer and an interconnection conductor has poor atomic diffusion capability, affecting the interface bonding effect, so that when ultrasonic wire bonding is performed using copper wires, copper ribbons, silver wires, or silver ribbons, a larger bonding force must be applied, which is also a major cause of chip cracking.

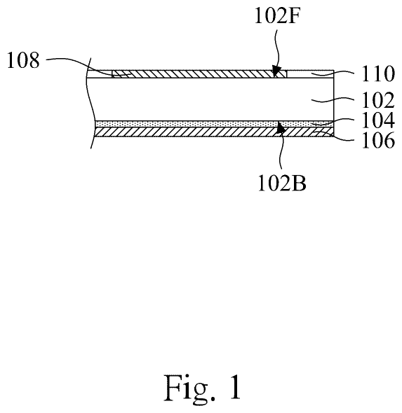

FIGS. 1 to 4 are partial cross-sectional views illustrating different process stages of forming a package structure according to some embodiments of the present disclosure.

Referring to FIG. 1, a chip 102 having a chip pad 108 is provided. The chip 102 has two opposite side surfaces, such as a frontside 102F and a backside 102B opposite to the frontside 102F. Specifically, the chip pad 108 is located on the frontside 102F of the chip 102. In some embodiments, the chip pad 108 is disposed in the same layer as a dielectric layer 110. For example, the chip pad 108 and the dielectric layer 110 are part of a redistribution layer (RDL) in the chip 102. The chip pad 108 is formed in the topmost dielectric layer 110, and the upper surface of the chip pad 108 is substantially coplanar (e.g., flush) with the upper surface of the dielectric layer 110. In some embodiments, the chip 102 is not configured with a chip pad 108.

In some embodiments, the chip 102 may include a power integrated circuit (IC) chip, but the present disclosure is not limited thereto. In other embodiments, the chip 102 is a chip for other purposes, such as a driver IC chip or a controller IC chip. In some embodiments, the power IC chip may include the 1^{st} generation semiconductor material (e.g., silicon (Si) or germanium (Ge)), the 3^{rd} generation semiconductor material (e.g., silicon carbide (SiC) or gallium nitride (GaN)), or the 3^{th} generation semiconductor material (e.g., gallium oxide (Ga₂O₃)).

In some embodiments, the chip pad 108 may include or be an aluminum pad or a copper pad. As needed, its surface may be plated with nickel, gold, palladium, alloys thereof, stacked layers thereof, or other suitable metal materials, which helps with corrosion prevention of the copper pad and/or bonding to other components. In some embodiments, the dielectric layer 110 may include or be silicon dioxide, silicon nitride, silicon oxynitride, polyimide, or other suitable dielectric materials.

In some embodiments, the chip 102 may optionally include a backside adhesion layer 104 and a backside reaction layer 106 disposed on the backside 102B. The backside adhesion layer 104 is disposed between the chip 102 and the backside reaction layer 106 to provide better bonding force between the chip 102 and the backside reaction layer 106. In some embodiments, the materials of the backside adhesion layer 104 may include titanium, chromium, titanium-tungsten, combinations thereof, or other suitable bonding materials. A thickness of the backside adhesion layer 104 may be 0.05 to 1 micrometer. In some embodiments, the backside adhesion layer 104 may be formed on the backside 102B of the chip 102 by means of sputtering, evaporation, or electroplating.

In some embodiments, the backside reaction layer 106 can serve as a metal layer for bonding and/or heat conduction, e.g., nickel, copper, silver, tin, combinations thereof, alloys thereof, or other suitable metal materials. In some embodiments, a thickness of the backside reaction layer 106 may be 0.3 to 10 micrometers. In some embodiments, the backside reaction layer 106 may be formed on the backside 102B of the chip 102 (e.g., on the backside adhesion layer 104) via a backside metallization process. The chip is then subjected to die bonding by soldering, conductive paste, or sintering paste to bond the backside reaction layer to the copper pad over the substrate.

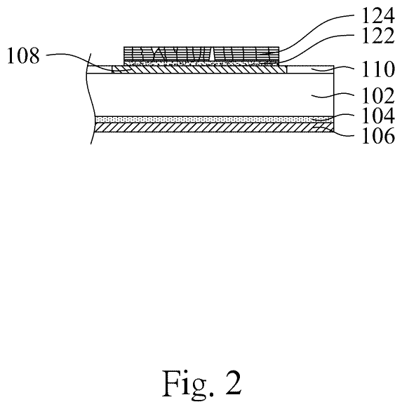

Referring to FIG. 2, a metal pressure-resistant layer 124 is disposed on the chip pad 108 of the chip 102, and the metal pressure-resistant layer 124 is electrically connected to the chip pad 108. Therefore, the chip pad 108 is disposed between the chip 102 and the metal pressure-resistant layer 124, so that the metal pressure-resistant layer 124 is electrically connected to the chip 102 through the chip pad 108. The metal pressure-resistant layer 124 has a nano-twinned structure, and a thickness of the metal pressure-resistant layer 124 is 2 to 20 micrometers. In some embodiments, an adhesion layer 122 may be formed on the chip pad 108 as needed before the metal pressure-resistant layer 124 is formed to increase the bonding force between the chip 102 and the metal pressure-resistant layer 124. In other words, the adhesion layer 122 is sandwiched between the chip 102 and the metal pressure-resistant layer 124. In some embodiments, a width of the chip pad 108 is greater than a width of the adhesion layer 122 and a width of the metal pressure-resistant layer 124, and thus the dielectric layer 110 is separated from the metal pressure-resistant layer 124. In some embodiments, the adhesion layer 122 can also provide a lattice buffering effect, preventing the nano-twinned structure in the metal pressure-resistant layer 124 from being affected by the crystallographic orientation of the chip 102. In some embodiments, the adhesion layer 122 may include or be tungsten, titanium, chromium, or alloys thereof. In some embodiments, a thickness of the adhesion layer 122 may be 0.05 to 3 micrometers (e.g., 0.1 to 0.5 micrometers). It should be understood that the thickness of the adhesion layer 122 can be adjusted appropriately according to practical applications, and the present disclosure is not limited thereto. In some embodiments, methods of forming the adhesion layer 122 may include sputtering, evaporation, or electroplating.

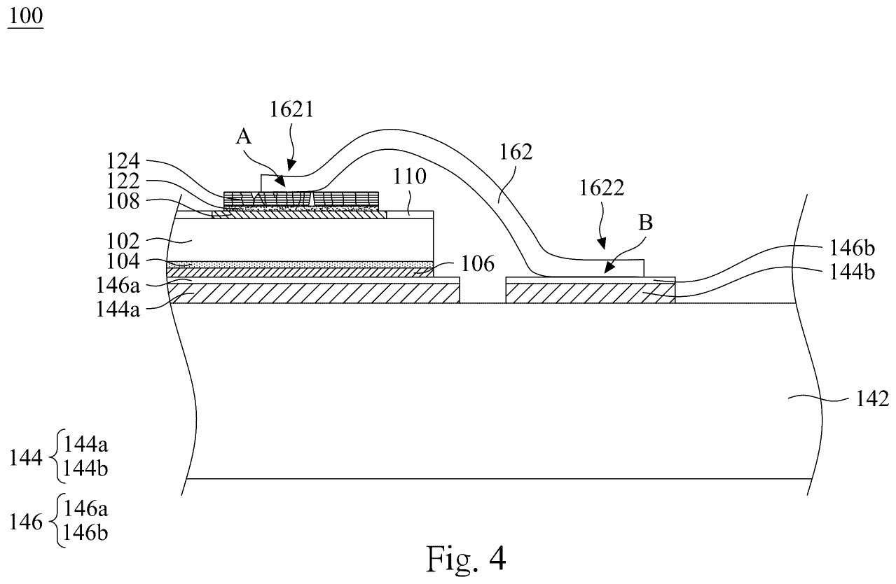

In some embodiments, the metal pressure-resistant layer 124 having the nano-twinned structure is formed over the chip pad 108 (or the adhesion layer 122, if present). In some embodiments, the nano-twinned structure has a plurality of twin boundaries arranged in parallel, and a spacing between any two adjacent boundaries of the plurality of twin boundaries arranged in parallel is 1 to 50 nanometers (e.g., 2 to 10 nanometers). In one embodiment, the spacing between any two adjacent boundaries of the twin boundaries arranged in parallel is any rational number within 1 to 50 nanometers, for example, 1 nanometer, 2 nanometers, 5 nanometers, 10 nanometers, 15 nanometers, 20 nanometers, 24 nanometers, 25 nanometers, 30 nanometers, 35 nanometers, 40 nanometers, 45 nanometers, or 50 nanometers. In a cross-sectional metallographic image of the metal pressure-resistant layer 124, regions with the plurality of twin boundaries arranged in parallel account for more than 20% of the metal pressure-resistant layer (e.g., any rational number within 20% to 100%, such as 20%, 25%, 30%, 35%, 40%, 45%, 50%, 55%, 60%, 65%, 70%, 75%, 80%, 85%, 90%, or 100%), and a nano-twin density in an upper region of the metal pressure-resistant layer 124 must be at least 80% and less than 100% (e.g., any rational number between 80% and 99%, such as 80%, 85%, 90%, 95%, or 99%). That is, the nano-twinned structure inside the metal pressure-resistant layer 124 may be uniformly distributed, or the nano-twinned structure may be concentrated in a staircase arrangement or floating arrangement in the upper region of the metal pressure-resistant layer 124 while a remaining region of the metal pressure-resistant layer 124 consists of randomly arranged grains. In some embodiments, the configuration of the nano-twinned structure inside the metal pressure-resistant layer 124 can be determined through cross-sectional images. Specifically, based on a cross-sectional image of the metal pressure-resistant layer 124, if the entire nano-twinned layer is of a twinned structure, then the nano-twinned structure inside the metal pressure-resistant layer 124 is determined to be uniformly distributed; if the nano-twinned layer has a twinned structure configured in a gradient distribution from bottom to surface in the upper region of the metal pressure-resistant layer 124, then the nano-twinned structure inside the metal pressure-resistant layer 124 is determined to be concentrated in a staircase arrangement in the upper region of the metal pressure-resistant layer 124; and if only an island-like twinned structure is configured on the surface of the upper region of the metal pressure-resistant layer 124, then the nano-twinned structure inside the metal pressure-resistant layer 124 is determined to be concentrated in a floating arrangement in the upper region of the metal pressure-resistant layer 124. In some embodiments, the metal pressure-resistant layer 124 having a nano-twinned structure can be used to prevent cracking of the chip 102 during ultrasonic wire bonding. This part will be explained in detail later with reference to FIG. 4.

The formation of a twin structure results from accumulated strain energy within the material, which drives uniform shear of atoms in certain regions to lattice positions that are mirror-symmetric with respect to unsheared atoms within their parent grains. There are three types of twins: annealing twin, mechanical twin, and the nano-twin of the present invention. Their mutually symmetric interface is the twin boundary. Twinning primarily occurs in face-centered cubic (FCC) or hexagonal closed-packed (HCP) crystalline materials with the closest lattice packing. Besides the condition of the crystal structure with the closest lattice packing, materials with lower stacking fault energy typically exhibit a greater tendency toward twinning. The nano-twin of the present invention is characterized primarily by the parallel-arranged stacking of multiple twin grains with thickness at the nanometer scale, and the twin boundaries of individual twin grains all have a (111) crystallographic orientation.

The twin boundaries are coherent crystal structures, belonging to low-energy Σ3 and Σ9 special grain boundaries. The crystallographic orientation is a (111) plane. Compared to high-angle grain boundaries formed by conventional annealing recrystallization, the boundary energy of twin boundaries is about 5% of that of general high-angle grain boundaries. Due to the lower boundary energy of the twin boundaries, they avoid becoming pathways for oxidation, sulfidation, and chloride ion corrosion. Therefore, they exhibit better oxidation resistance and corrosion resistance. Furthermore, such symmetric lattice arrangement of twins poses less hindrance to electron transport. Consequently, they exhibit better electrical conductivity and thermal conductivity. Due to the obstruction of the twin boundaries to the dislocation movement, the material can still maintain high strength. This combination of high strength and high electrical conductivity has been confirmed in copper thin films.

Regarding high-temperature stability, due to the lower boundary energy of the twin boundaries, the twin boundaries are more stable than general high-angle grain boundaries. The twin boundaries themselves exhibit low mobility at high temperatures and also exert a pinning effect on the surrounding high-angle grain boundaries, thereby preventing movement of these high-angle grain boundaries. Consequently, the overall grains exhibit no significant grain growth at high temperatures, thereby maintaining the high-temperature strength of the material. Regarding reliability under current flow, the diffusion rate of atoms via low-energy twin boundaries or across twin boundaries is low. When an electronic product is used, the movement of atoms inside wires accompanying high-density current flow also becomes more difficult. This solves the electromigration problem that frequently occurs in wires during current flow. It has been reported in copper thin films that twins can suppress material electromigration phenomena.

Additionally, the nano-twinned structure also has many advantages. For example, the strength of nano-twinned thin films is about 10 times higher than that of conventional metals with randomly oriented grains, but the electrical conductivity remains unchanged, which is beneficial for improving the electrical performance of ultrasonic-bonded interconnection packages. The hardness of nano-twinned structure thin films is also higher than that of conventional thin films with randomly oriented grains, thereby preventing chip cracking during ultrasonic bonding. Furthermore, the nano-twinned structure has a high-density (111) crystallographic orientation, and it is known that atomic diffusion rates along the (111) crystallographic orientation exceed those along a (100) or (110) orientation by 3-5 orders of magnitude. Therefore, nano-twinned metals possess extremely high atomic diffusion capability, which also facilitates the formation of ultrasonic bonding interfaces.

In some embodiments, the metal pressure-resistant layer 124 may include or be silver, copper, nickel, palladium, or gold. In some embodiments, the metal pressure-resistant layer 124 consists of a nano-twinned structure having a thickness of 2 to 20 micrometers (e.g., 4 micrometers, 8 micrometers, or 15 micrometers). When the thickness of the metal pressure-resistant layer 124 is less than 2 micrometers, it cannot effectively reduce the load during ultrasonic wire bonding to avoid cracking of the chip 102, and its nano-twinned layer with the (111) preferential crystallographic orientation is insufficient to provide fast atomic diffusion paths for the ultrasonic bonding interface; and when the thickness of the metal pressure-resistant layer 124 is greater than 20 micrometers, the metal pressure-resistant layer 124 is prone to peeling off from the adhesion layer 122 on the chip 102, especially when a wafer that has been covered with the metal pressure-resistant layer is diced, peeling of the metal pressure-resistant layer is more likely to occur. Moreover, the production time for the metal pressure-resistant layer used to cover the wafer is too long, and the cost is higher.

In some embodiments, the metal pressure-resistant layer 124 may be formed by means of sputtering, evaporation, or electroplating. According to some embodiments, sputtering is implemented using a single-gun or multi-gun co-sputtering. A sputtering power supply may be configured to provide, for example, direct current (DC), pulsed DC, radio frequency (RF), or the power for high-power impulse magnetron sputtering (HIPIMS). The sputtering power for the metal pressure-resistant layer 124 may range from, for example, about 100 W to about 500 W. The sputtering process initiates at ambient temperature, but the temperature during sputtering will rise by about 50° C. to about 200° C. The deposition rate of the metal pressure-resistant layer 124 may range from, for example, about 0.5 nm/s to about 3 nm/s. The base pressure in sputtering is less than 1×10⁻⁵ torr, and the working pressure may range from, for example, about 1×10⁻³ torr to 1×10⁻² torr. The argon flow rate ranges from about 10 sccm to about 20 sccm. The stage rotation speed may range from, for example, about 5 rpm to about 20 rpm. A bias voltage of about −100V to about −200V is applied to the substrate during sputtering, where application of an appropriate bias voltage to the substrate during sputtering is a key means for forming high-density nanotwins. It should be understood that the above sputtering process parameters may be adjusted appropriately according to practical applications; and the present disclosure is not limited thereto.

According to further embodiments, the metal pressure-resistant layer 124 may be formed by means of evaporation. The base pressure during evaporation is less than 1×10⁻⁵ torr, the working pressure may range from, for example, about 1×10⁻⁴ torr to about 5×10⁻⁴ torr, and the argon flow rate is about 2 sccm to about 10 sccm. The stage rotation speed may range from, for example, about 5 rpm to about 20 rpm. The deposition rate of the metal pressure-resistant layer 124 may range from, for example, about 1 nm/s to about 5.0 nm/s. Ion bombardment is additionally applied to the metal pressure-resistant layer 124 during evaporation, at a voltage of about 10V to about 300V and a current of about 0.1 A to about 1.0 A, where application of ion bombardment to the metal pressure-resistant layer during evaporation is a key means for forming high-density nanotwins. It should be understood that the above evaporation process parameters may be adjusted appropriately according to practical applications; and the present disclosure is not limited thereto.

According to some further embodiments, the metal pressure-resistant layer 124 can be formed by electroplating. Agitation of electroplating solution at a high rotational speed of 500 to 1000 rpm concurrently with the electroplating process constitutes a critical technique for forming high-density nanotwins.

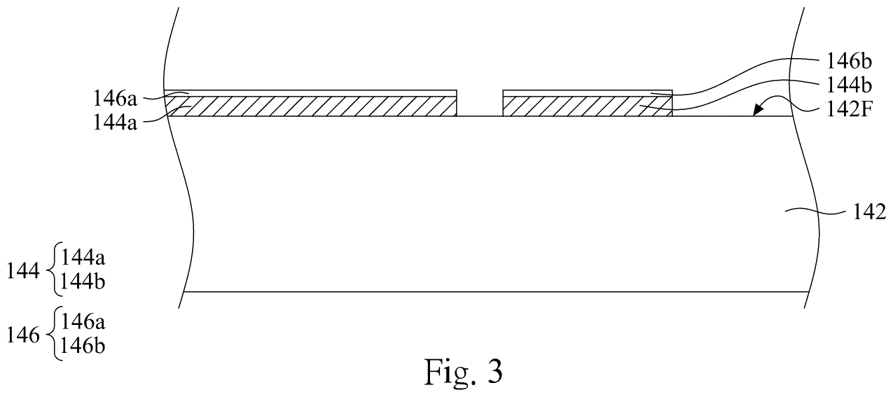

Referring to FIG. 3, a substrate 142 having substrate pads 144a, 144b is provided. In some embodiments, the substrate pad 144a and the substrate pad 144b are disposed on the substrate 142 and spaced apart from each other. To simplify the figure, only one substrate pad 144b is shown in the substrate 142 in the figure, but the present disclosure is not limited thereto. In further embodiments, when the chip 102 has a plurality of chip pads 108, a plurality of substrate pads 144b spaced apart from each other may also be provided on the substrate 142, corresponding to the plurality of chip pads 108 respectively. For simplicity, the substrate pads 144a, 144b may sometimes be collectively referred to as substrate pad 144.

In some embodiments, the substrate 142 may include a printed circuit board (PCB) ceramic substrate, a lead frame, or an insulated metal substrate (IMS) (or may be called an insulated metal baseplate (IMB)). The ceramic substrate may include aluminum oxide (Al₂O₃), aluminum nitride (AlN), or silicon nitride (Si₃N₄). In some embodiments, the substrate pad 144 is part of a patterned circuit layout and disposed on a surface 142F of the substrate 142. In some embodiments, the substrate pads 144a and 144b include or are copper. The substrate pads 144a and 144b are disposed on the substrate 142 by direct bonded copper (DBC), direct plated copper (DPC), or active metal brazing (AMB).

In some embodiments, the substrate 142 optionally includes protective films 146a, 146b respectively disposed on surfaces of the substrate pads 144a, 144b over the substrate 142. As shown in FIG. 4, the protective film 146a is disposed on the substrate pad 144a over the substrate 142, and the protective film 146b is disposed on the substrate pad 144b over the substrate 142. The respective thicknesses of the substrate pads 144 a and 144 b are about 0.5 to 1 millimeter (mm), for example, 0.635 mm. For simplicity, the protective films 146a, 146b may sometimes be collectively referred to as protective film 146. The protective film 146 is configured to prevent the substrate pad 144 from oxidization or corrosion due to exposure to air under normal environmental conditions. In some embodiments, the protective film 146 may include or be a metal thin film. The metal thin film may include or be nickel (Ni), nickel/gold (Ni/Au), nickel/palladium/gold (Ni/Pd/Au), silver (Ag), or nickel/silver (Ni/Ag), or the metal thin film may have a nano-twinned structure. In some embodiments, the protective film 146 may have different thicknesses of 0.1 to 100 micrometers depending on different metal thin films. In some embodiments, the package structure 100 may not be configured with the protective film 146.

Referring to FIG. 4, the chip 102 is bonded to the substrate 142. As shown in FIG. 1 and FIG. 4, the backside 102B faces the substrate 142. For example, the chip 102 is bonded to the substrate pad 144a (or the protective film 146a, if present) of the substrate 142 via the backside reaction layer 106 located on the backside 102B. In some embodiments, the chip 102 may be bonded to the substrate 142 by means of die bonding such as gold/silicon eutectic bonding, adhesive bonding, solder bonding, or sintering bonding, but the present disclosure is not limited thereto.

In some embodiments, the metal pressure-resistant layer 124 and the substrate pad 144b are electrically connected to each other via an interconnection conductor 162 by means of ultrasonic wire bonding, such that one end 1621 of the interconnection conductor 162 is electrically connected to the chip pad 108 through the metal pressure-resistant layer 124, while the other end 1622 is electrically connected to the substrate pad 144b. Thus, the chip 102 may be electrically connected to the substrate 142 via the chip pad 108, the metal pressure-resistant layer 124, the interconnection conductor 162, and the substrate pad 144b. Specifically, first, the one end 1621 of the interconnection conductor material is ultrasonically wire-bonded to the metal pressure-resistant layer 124 to form a first bond point A, then the other end 1622 of the interconnection conductor material is ultrasonically wire-bonded to the substrate pad 144b to form a second bond point B. In some embodiments, after the second bond point B is formed, the interconnection conductor material is clipped to form the interconnection conductor 162 having the first bond point A and the second bond point B.

In some embodiments, ultrasonic bonding is performed under process conditions of ultrasonic vibration power of 50 to 300 milliwatts (mW), bonding time of 100 to 150 milliseconds (ms), and load of 200 to 1000 centinewton (cN) (e.g., 400 to 600 cN), to bond a metal heavy wire or ribbon to the metal pressure-resistant layer 124 without causing cracking of the chip 102. In some embodiments of the present disclosure, unless specifically defined, the term “load” refers to the intensity applied to the bonding point during the ultrasonic bonding process.

In detail, since the surface of the metal pressure-resistant layer 124 has a nano-twinned structure with over 80% high-density (111) crystallographic orientation, it can more effectively enhance the atomic diffusion reaction with the metal wire or ribbon during ultrasonic wire bonding and accelerate the formation of bonding interfaces. Therefore, the load for ultrasonic wire bonding can be significantly reduced, thereby effectively preventing cracking of the chip 102. Furthermore, the nano-twinned structure has high hardness, which can further protect the underlying chip 102 from cracking when ultrasonic wire bonding is performed using copper wires, copper ribbons, silver wires, or silver ribbons. In some embodiments, compared to use of coarse-grained metals, use of the metal pressure-resistant layer 124 with a nano-twinned structure can reduce the load by more than 30%.

In some embodiments, the interconnection conductor 162 is configured to provide signal and power transmission between the chip 102 and the substrate 142, and may also serve heat dissipation functions. In some embodiments, the interconnection conductor 162 is selected from a group consisting of: aluminum wires, aluminum ribbons, copper wires, copper ribbons, aluminum-plated copper wires, aluminum-plated copper ribbons, silver alloy wires, and silver alloy ribbons. In some embodiments of the present disclosure, unless specifically defined, the term “ribbon” refers to a substantially flat-plate-shaped continuous elongated strip having a thickness of 10 to 500 micrometers and a width 2 to 200 times the thickness but typically not exceeding 5 millimeters (mm). The term “wire” refers to a continuous long wire with a substantially circular cross-section and a diameter of 100 micrometers or more, which is much larger than the diameter of fine wires (all less than 25.4 micrometers) used for thermocompression wire bonding in general ICs or LEDs.

As shown in FIG. 4, the present disclosure provides a package structure 100 including a substrate 142 having a substrate pad 144b; a chip 102 disposed over the substrate 142 and having a chip pad 108; a metal pressure-resistant layer 124 disposed over the chip pad 108 and having a nano-twinned structure; and an interconnection conductor 162. One end of the interconnection conductor 162 is electrically connected to the chip pad 108 via the metal pressure-resistant layer 124, and the other end is electrically connected to the substrate pad 144b.

The following describes test results of some experimental examples and comparative examples of the package structure according to the present disclosure.

### Comparative Example 1: SiC/Cr/Cu Structure

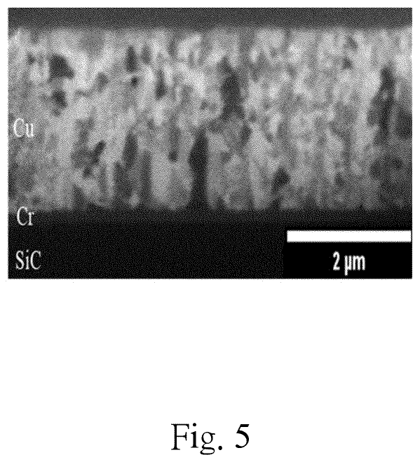

FIG. 5 shows a cross-sectional metallographic image of a SiC/Cr/Cu structure obtained using a focused ion beam (FIB) according to some embodiments. The SiC/Cr/Cu structure is an example similar to the package structure 100 of FIG. 4, but has a coarse-grained metal layer (i.e., without a nano-twinned structure; not shown) therein to replace the metal pressure-resistant layer 124. Specifically, the chip 102 is silicon carbide (SiC), the adhesion layer 122 is chromium (Cr), and the metal pressure-resistant layer 124 is replaced with coarse-grained copper (Cu) having a thickness of 4 micrometers.

### Comparative Example 2: SiC/Cr/Ni/Ag Structure

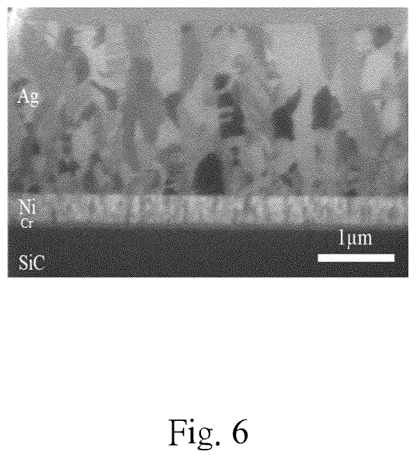

FIG. 6 shows a cross-sectional metallographic image of a SiC/Cr/Ni/Ag structure obtained using an FIB according to some embodiments. The SiC/Cr/Ni/Ag structure is an example similar to the package structure 100 of FIG. 4, but has a coarse-grained metal layer (i.e., without a nano-twinned structure; not shown) therein to replace the metal pressure-resistant layer 124. Specifically, the chip 102 is silicon carbide (SiC), the adhesion layer 122 is chromium/nickel (Cr/Ni), and the metal pressure-resistant layer 124 is replaced with coarse-grained silver (Ag) having a thickness of 4 micrometers.

### Experimental Example 1: SiC/Cr/nt-Cu Structure

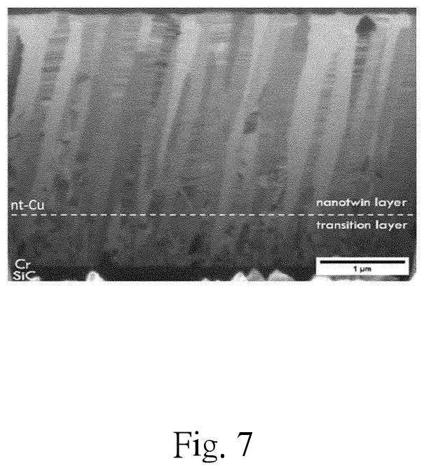

FIG. 7 shows a cross-sectional metallographic image of a SiC/Cr/nt-Cu structure obtained using an FIB according to some experimental examples. The SiC/Cr/nt-Cu structure is an example of the package structure 100 of FIG. 4, where the chip 102 is silicon carbide (SiC), the adhesion layer 122 is chromium (Cr), and the metal pressure-resistant layer 124 is copper nanotwins (nt-Cu) having a nano-twinned (nt) structure.

### Experimental Example 2: SiC/Cr/nt-Ag Structure

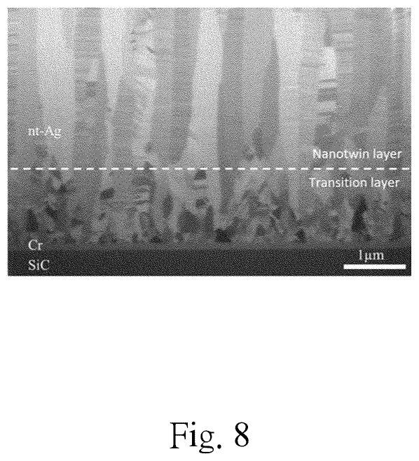

FIG. 8 shows a cross-sectional metallographic image of a SiC/Cr/nt-Ag structure obtained using an FIB according to some experimental examples. The SiC/Cr/nt-Ag structure is an example of the package structure 100 of FIG. 4, where the chip 102 is silicon carbide (SiC), the adhesion layer 122 is chromium (Cr), and the metal pressure-resistant layer 124 is silver nanotwins (nt-Ag) having a nano-twinned (nt) structure.

### Ultrasonic Bonding Using Copper Ribbons

Ultrasonic wire bonding was performed on silicon carbide chips with metal pressure-resistant layers in Comparative Examples 1-2 and Experimental Examples 1-2 using a copper ribbon (width: 1.5 mm; thickness: 0.15 mm). Results show that when the ultrasonic wire power is 200 mW and the load is 300 cN or less, no cracking occurs in the silicon carbide chips with the metal pressure-resistant layers in Comparative Examples 1-2 and Experimental Examples 1-2. However, the chips having randomly-grained metal pressure-resistant layers from Comparative Examples 1-2 fail to be bonded to the copper ribbon, while the chips having nano-twinned metal pressure-resistant layers in Experimental Examples 1-2 can be bonded to the copper ribbon. When the load for ultrasonic wire bonding is increased to 500 cN, although the silicon carbide chips with the metal pressure-resistant layers in Comparative Examples 1-2 and Experimental Examples 1-2 can be bonded to the copper ribbon, most chips having the randomly-grained metal pressure-resistant layers in Comparative Examples 1-2 crack, while none of the chips having nano-twinned metal pressure-resistant layers in Experimental Examples 1-2 crack, and the second bond point is successfully bonded to the pad on the substrate 142. Results of ultrasonic bonding performed on the chips with copper and silver metal pressure-resistant layers in Experimental Examples 1-2 using the copper ribbon are similar.

### Ultrasonic Bonding Using Copper Wires

Ultrasonic wire bonding was performed on silicon carbide chips with metal pressure-resistant layers from Comparative Examples 1-2 and Experimental Examples 1-2 using a copper wire (diameter: 380 μm). Results show that when the ultrasonic wire bonding power is 85.5 mW and the load is 300 cN, no cracking occurs in the silicon carbide chips with the metal pressure-resistant layers in Comparative Examples 1-2 and Experimental Examples 1-2, but most of the results show poor bonding or fail to be bonded to the copper wire. When the load is increased to 500 cN, most of the chips still don't crack, but the chips having the randomly-grained metal pressure-resistant layers in Comparative Examples 1-2 suffer poor bonding or fail to be bonded to the copper wire, while most of the chips having nano-twinned metal pressure-resistant layers in Experimental Examples 1-2 can be bonded to the copper wire. When the ultrasonic wire bonding load is increased to 800 cN, although both the silicon carbide chips with the metal pressure-resistant layers in Comparative Examples 1-2 and Experimental Examples 1-2 can be bonded to the copper wire, most of the chips with randomly-grained metal pressure-resistant layers in Comparative Examples 1-2 crack, while a few chips with nano-twinned metal pressure-resistant layers in Experimental Examples 1-2 show cracks. Results of ultrasonic bonding performed on chips with copper and silver metal pressure-resistant layers in Experimental Examples 1-2 using the copper wire are similar.

Based on the results of ultrasonic wire bonding using the copper ribbon and the copper wire, it can be confirmed that for Experimental Examples (using the metal pressure-resistant layer 124 with a nano-twinned structure), applying a load of 500 cN during ultrasonic bonding enables the bonding between the copper ribbon/copper wire and the metal pressure-resistant layer 124 to be completed without cracking of the chip 102. In contrast, for Comparative Examples (using randomly-grained metal layers without a nano-twinned structure), when ultrasonic wire bonding using the copper ribbon is performed, although bonding can be achieved by applying a 500 cN load, there's already a risk of chip cracking. Furthermore, for chips with the randomly-grained metal layer in Comparative Examples undergoing ultrasonic bonding using a copper wire, the load must be increased to 800 cN to complete bonding, but the chip 102 suffers severe cracking. From the above results of ultrasonic wire bonding using the copper ribbon and the copper wire, it can be concluded that the metal pressure-resistant layer 124 with a nano-twinned structure enables bonding to be completed at lower loads and/or prevents cracking of the chip 102 during ultrasonic bonding.

The embodiments of the present disclosure possess several advantageous features. The metal pressure-resistant layer disposed over the chip, due to its nano-twinned structure, can effectively enhance the atomic diffusion reaction of a metal wire or ribbon during ultrasonic wire bonding and accelerate the formation of bonding interfaces. Consequently, this allows for a reduction in the applied load during ultrasonic bonding to prevent cracking of the chip. Furthermore, the nano-twinned structure exhibits high hardness, which can further protect the underlying chip from cracking during ultrasonic wire bonding using copper wires, copper ribbons, silver wires, or silver ribbons.

The components of several embodiments are outlined above so that persons having ordinary skill in the art to which the present invention pertains can more readily understand the perspectives of the embodiments of the present invention. Persons having ordinary skill in the art to which the present invention pertains should understand that they may use the embodiments of the present invention as a basis to design or modify other processes and structures to achieve the same purposes and/or advantages as the embodiments described herein. Persons having ordinary skill in the art to which the present invention pertains should also understand that such equivalent processes and structures do not depart from the spirit and scope of the present invention, and that they may make various changes, substitutions, and alterations without departing from the spirit and scope of the present invention.

What is claimed is:

1. A package structure, comprising:
a substrate;
a first substrate pad disposed on the substrate;
a chip disposed over the substrate and having a first side surface and a second side surface opposite to the first side surface, the second side surface facing the substrate;
a chip pad located on the first side surface of the chip;
a dielectric layer disposed in the same layer as the chip pad;
a metal pressure-resistant layer disposed on the chip pad, electrically connected to the chip pad, and having a first nano-twinned structure, wherein the chip pad is disposed between the first side surface of the chip and the metal pressure-resistant layer, and the dielectric layer is separated from the metal pressure-resistant layer;
a first adhesion layer sandwiched between the metal pressure-resistant layer and the chip pad, and formed from a material different from a material of the metal pressure-resistant layer; and
an interconnection conductor having one end electrically connected to the metal pressure-resistant layer and the other end electrically connected to the first substrate pad;
wherein a width of the chip pad is greater than a width of the first adhesion layer and a width of the metal pressure-resistant layer.

2. The package structure according to claim 1, further comprising a protective film disposed on the first substrate pad, wherein the protective film comprises a metal thin film.

3. The package structure according to claim 2, wherein the metal thin film has a second nano-twinned structure.

4. The package structure according to claim 1, wherein an upper surface of the chip pad and an upper surface of the dielectric layer are coplanar.

5. The package structure according to claim 1, wherein the first nano-twinned structure has a plurality of twin boundaries arranged in parallel, and a spacing between any two adjacent boundaries of the plurality of the twin boundaries is 1 to 50 nanometers.

6. The package structure according to claim 1, further comprising a second substrate pad disposed on the substrate and spaced apart from the first substrate pad, wherein the chip is disposed on the second substrate pad.

7. The package structure according to claim 1, wherein the first adhesion layer comprises tungsten, titanium, chromium, or an alloy thereof.

8. The package structure according to claim 1, wherein a thickness of the metal pressure-resistant layer is 2 to 20 micrometers.

9. The package structure according to claim 1, wherein the first nano-twinned structure is concentrated in a staircase arrangement or floating arrangement in an upper region of the metal pressure-resistant layer, and a remaining region of the metal pressure-resistant layer consists of randomly arranged grains.

10. The package structure according to claim 1, wherein the interconnection conductor is a continuous elongated strip having a thickness of 10 to 500 micrometers and a width 2 to 200 times the thickness or a continuous long wire having a circular cross-section with a diameter of 100 micrometers or more, and one end of the interconnection conductor is ultrasonically wire-bonded to the metal pressure-resistant layer.

11. The package structure according to claim 1, further comprising:
a second adhesion layer disposed on the second side surface of the chip; and
a backside reaction layer disposed on the second side surface of the chip, wherein the second adhesion layer is between the chip and the backside reaction layer.

12. A method of manufacturing a package structure, comprising:
providing a chip that has a first side surface and a second side surface opposite to the first side surface;
disposing a chip pad that is located on the first side surface of the chip;
disposing a dielectric layer that is disposed in the same layer as the chip pad;
forming a first adhesion layer on the chip pad;
forming a metal pressure-resistant layer having a first nano-twinned structure over the chip pad, such that the metal pressure-resistant layer is electrically connected to the chip pad, wherein the chip pad is disposed between the first side surface of the chip and the metal pressure-resistant layer, the dielectric layer is separated from the metal pressure-resistant layer, and the first adhesion layer is sandwiched between the metal pressure-resistant layer and the chip pad and formed from a material different from a material of the metal pressure-resistant layer;
providing a substrate having a substrate pad, wherein the second side surface of the chip faces the substrate;
bonding the chip to the substrate; and
electrically connecting the metal pressure-resistant layer to the substrate pad via an interconnection conductor;
wherein a width of the chip pad is greater than a width of the first adhesion layer and a width of the metal pressure-resistant layer.

13. The method of manufacturing a package structure according to claim 12, further comprising:
disposing a protective film on the substrate pad, wherein the protective film comprises a metal thin film, and the metal thin film has a second nano-twinned structure.

14. The method of manufacturing a package structure according to claim 12, wherein the electrically connecting the metal pressure-resistant layer to the substrate pad via the interconnection conductor comprises:
ultrasonically wire-bonding one end of the interconnection conductor to the metal pressure-resistant layer to form a first bond point, and then ultrasonically wire-bonding the other end of the interconnection conductor to the substrate pad to form a second bond point.

15. The method of manufacturing a package structure according to claim 12, wherein the first nano-twinned structure is concentrated in a staircase arrangement or floating arrangement in an upper region of the metal pressure-resistant layer, and a remaining region of the metal pressure-resistant layer consists of randomly arranged grains.

16. The method of manufacturing a package structure according to claim 12, wherein the interconnection conductor is a continuous elongated strip having a thickness of 10 to 500 micrometers and a width 2 to 200 times the thickness or a continuous long wire having a circular cross-section with a diameter of 100 micrometers or more, and one end of the interconnection conductor is ultrasonically wire-bonded to the metal pressure-resistant layer.

17. The method of manufacturing a package structure according to claim 12, further comprising:
disposing a second adhesion layer on the second side surface of the chip; and
disposing a backside reaction layer on the second side surface of the chip, wherein the second adhesion layer is between the chip and the backside reaction layer.

18. A package structure, comprising:
a substrate;
a first substrate pad disposed on the substrate;
a chip disposed over the substrate;
a chip pad located on a first side surface of the chip;
a metal pressure-resistant layer electrically connected to the chip pad and having a nano-twinned structure;
a first adhesion layer sandwiched between the metal pressure-resistant layer and the chip pad, and formed from a material different from a material of the metal pressure-resistant layer; and
an interconnection conductor having one end electrically connected to the metal pressure-resistant layer and the other end electrically connected to the first substrate pad;
wherein a width of the chip pad is greater than a width of the first adhesion layer and a width of the metal pressure-resistant layer; and
wherein the nano-twinned structure is concentrated in a staircase arrangement or floating arrangement in an upper region of the metal pressure-resistant layer, and a remaining region of the metal pressure-resistant layer consists of randomly arranged grains.

19. The package structure according to claim 18, wherein the interconnection conductor is a continuous elongated strip having a thickness of 10 to 500 micrometers and a width 2 to 200 times the thickness or a continuous long wire having a circular cross-section with a diameter of 100 micrometers or more, and one end of the interconnection conductor is ultrasonically wire-bonded to the metal pressure-resistant layer.

20. The package structure according to claim 18, further comprising:
a second adhesion layer disposed on a second side surface of the chip, wherein the second side surface is opposite to the first side surface; and
a backside reaction layer disposed on the second side surface of the chip, wherein the second adhesion layer is between the chip and the backside reaction layer.
